(19) United States
(12) Patent Application Publication
(10) Pub. No.: US 2014/0144427 A1
(43) Pub. Date: May 29, 2014

(54) POLYMERIC MATERIALS FOR EXTERNAL APPLICATIONS WITH SELF-HEALING SURFACE PROPERTIES AFTER SCRATCHES OR ABRASION DAMAGE

(71) Applicants: Uwe Numrich, Gross-Zimmern (DE); Waldemar Kanzler, Bietigheim-Bissingen (DE); Maren Szallies, Grosskrotzenburg (DE); Jochen Ackermann, Muehital (DE); Michael Olbrich, Karlstein (DE)

(72) Inventors: Uwe Numrich, Gross-Zimmern (DE); Waldemar Kanzler, Bietigheim-Bissingen (DE); Maren Szallies, Grosskrotzenburg (DE); Jochen Ackermann, Muehital (DE); Michael Olbrich, Karlstein (DE)

(73) Assignee: Evonik Roehm GmbH, Darmstadt (DE)

(21) Appl. No.: 14/130,619

(22) PCT Filed: Aug. 28, 2012
(86) PCT No.: PCT/EP12/66643

§ 371 Date: Jan. 2, 2014

(30) Foreign Application Priority Data
Sep. 14, 2011 (EP) 10 2011 113 160.8

(51) Int. Cl. F24J 2/10; H01L 31/0216; F24J 2/08

(52) U.S. Cl. CPC F24J 2/1057; F24J 2/08; H01L 31/0216
USPC 126/684; 126/698; 428/220; 428/215; 427/74; 524/545

(57) ABSTRACT

The invention relates to surface enhancements for composite mouldings made from polymeric materials and to the use thereof in solar systems. These solar systems may be solar reflectors for concentrating solar radiation, flexible photovoltaic composite films, or CPV (Concentrated Photovoltaics) lenses for concentrating solar radiation.

The surface enhancement comprises a self-healing coating based on crosslinkable fluoropolymers, e.g. PFEVE (polyfluoroethylene alkylvinyl ethers). These coatings exhibit good optical properties, can be used in outdoor applications, more particularly in solar applications, over very long periods of time, exhibit self-cleaning properties, and in particular are self-healing in relation to mechanical damage—such as scratching.

### FIELD OF THE INVENTION

The invention relates to surface enhancements for composite mouldings made from polymeric materials and to the use thereof in solar systems. These solar systems may be solar reflectors for concentrating solar radiation, flexible photovoltaic composite films, or CPV (Concentrated Photovoltaics) lenses for concentrating solar radiation.

The surface enhancement comprises a self-healing coating based on crosslinkable fluoropolymers, e.g. PFEVE (polyfluoroethylene alkylvinyl ethers). These coatings exhibit good optical properties, can be used in outdoor applications, more particularly in solar applications, over very long periods of time, exhibit self-cleaning properties, and in particular are self-healing in relation to mechanical damage—such as scratching.

### PRIOR ART

Polymeric composite mouldings in solar reflectors of the prior art have disadvantages in relation to sufficient longevity. Especially in outdoor applications over a period of 20 years or more, not only established glass mirrors but also, in particular, composite mouldings based on polymer layers are susceptible to superficial damage such as scratching. This may be caused, for example, by sand swirled up by the wind, or by cleaning with brushes.

This problem can be solved by coating with polysiloxanes, such as CRYSTALCOAT™ MP-100 from SDC Techologies Inc., AS 400-SHP 401 or UVHC3000K, both from Momentive Performance Materials. In a long-term application over a period of at least 20 years in an outdoor zone, this kind of application being required in particular for solar reflectors or photovoltaic cells, however, such materials fail to display sufficient abrasion resistance.

With the aim of improving the surface protection, U.S. Pat. No. 5,118,540 adheres abrasion-resistant and moisture-resistant film based on fluorocarbon polymers, such as PVDF. Both the UV absorption reagent and the corrosion inhibitor are part of the adhesive layer by which the film is joined to the metal surface of the vapour-deposited polyester support film. This adhesive layer, in the same way as for the dual (meth)acrylate coating set out above, may consist of two different layers, in order to separate corrosion inhibitor from UV absorption reagent. A coating of this kind, however, does not exhibit sufficient long-term stability to scratching.

Another prior-art solution are inorganic scratch-resistant coatings. EP 1 629 053 discloses one such coating, comprising silicon dioxide particles or aluminium oxide particles with diameters of less than 1 μm, for the coating of film laminates which find use as weather-resistant films. Inorganic coatings of these kinds, however, have the disadvantage that under the conditions customary in solar power stations, their durability is relatively short, i.e. not more than a few years. Blown sand, or even sand storms, or other climatic conditions, in a very hot and—especially—a dry environment, result in abrasion to such coatings.

WO 2010/078105 describes solar reflectors having a scratch-resistant coating on a polymeric basis, which can additionally be combined with an anti-soiling coating made of fluoropolymers or polysilicones. Coating materials given as improving the scratch resistance are thermoplastic polyurethanes (e.g. TECOFLEX® from Lubrizol) or crosslinkable polysiloxanes (e.g. PERMA-NEW 6000 from California Hardcoating Co.). Both coatings are of the type known as hardcoatings. Under prolonged, intense exposure, of the kind occurring, as described earlier on above, in deserts or on steppes, such systems also suffer scratching or abrasion. Furthermore, polysiloxanes do not have optimum UV stability under such intense long-term exposure.

### Object

One object was to provide an innovative surface enhancement for solar systems, more particularly for solar reflectors, flexible photovoltaic systems or CPV lenses. This surface enhancement is aimed at counteracting scratching and the associated reduction in efficiency in outdoor applications over a period of more than 15 years.

A further object was to provide solar systems equipped with this surface enhancement with optical properties and weathering resistance that at least match those of the prior art.

An additional object was to ensure long-term stability of the composite mouldings for solar reflectors under particularly strong insolation, of the kind which occurs, for example, in the Sahara or in the southwestern USA.

This applies more particularly in relation to the intrinsic stability and filtering efficiency of the surface-finishing layer of these composite mouldings with respect to the UV wavelength spectrum between 295 and 380 nm.

Another object, furthermore, was to provide surface enhancements for solar systems that are simple and cost-effective to produce and to apply.

### Achievement of Object

In the light of the prior art and of the inadequate technical solutions described therein for long-term applications, the present invention is successful in providing, in a manner not readily foreseeable by the person skilled in the art, a composite moulding having a surface quality improved over a long period of time. This is accomplished by provision of a composite moulding for use in solar systems of solar energy generation, the moulding having an outer layer having self-healing properties.

The term “self-healing property” refers in the context of this invention to the capacity of a layer of plastic, on exposure in particular to heat or electromagnetic radiation, such as UV radiation, to bring about a change in the surface of the material such that scratches or small cracks are closed up, while at the same time, under the same exposure, the basic form of the layer—in relation, for example, to its optical properties, the layer thickness and its distribution over the layer—is not altered. Self-healing layers of this kind include, for example, systems which are crosslinked physically, as for example by strong van-der-Waals' interactions, hydrogen bonds or ionic linkages. Through supply of energy, these crosslinks may be partly undone and joined up later on. In this variant, the supply of energy may be by means of heat or electromagnetic radiation.

In one particularly suitable variant, found surprisingly, the self-healing material of the outer layer has a glass transition temperature of between 10 and 70° C., preferably between 20 and 60° C. The material in this case is crosslinked preferably irreversibly.

The degree of crosslinking, accordingly, is preferably such that, firstly, the individual chain segments, above the glass transition temperature of the material, have a certain mobility, and, secondly, the resulting coating is sufficiently hard and abrasion-resistant.

The outer layer of the invention is constructed preferably on the basis of crosslinkable fluoropolymers, which optionally are formulated with further adjuvants.

Particularly preferred in this context are crosslinkable fluoropolymers which can be used as a solution polymer or as an aqueous dispersion.

Examples of crosslinkable fluoropolymers are block terpolymers of vinylidene difluoride, tetrafluoroethylene and a vinyl ester, such as vinyl butyrate, for example, or copolymers of tetrafluoroethylene and hydroxyalkyl vinyl ethers. The latter can be cured, for example, with hexa(methoxymethyl)melamine. For none of these polymers was it hitherto known that the coatings would have self-healing properties.

One particularly preferred example of a material for representing the outer layer of the invention, with these properties, are—surprisingly—poly(fluoroethylene alkylvinyl ethers) (PFEVE), of the kind sold, for example, under the name LUMIFLON® by Asahi Glass Chemicals.

PFEVE is understood generally to comprise copolymers of trifluoroethylene, tetrafluoroethylene or trifluorochloroethylene, on the one hand, and a vinyl ether, on the other. In such copolymerse, the fluoroethylene units and the vinyl ether units are usually incorporated in alternation in the chain. The copolymerized vinyl ethers generally constitute a mixture of different compounds, of which some may have an additional functionality. As well as polar groups, which are suitable for more effective dispersing of pigments, such as acid groups, for example, these functionalities may in particular be crosslinkable groups, such as double bonds, hydroxyl groups or epoxy groups.

Particularly surprisingly in the context of this invention it has been found that PFEVE-based coatings have self-healing properties, more particularly under the conditions characteristic of solar applications.

Since, furthermore, PFEVE is completely amorphous, the corresponding formulations and coatings have good optical properties and a high transparency. Furthermore, PFEVE possesses very good weathering stability over a very long timespan, even under extreme conditions. PFEVE-based coatings, then, are extremely UV-resistant and, furthermore, have very good barrier properties with respect to atmospheric oxygen and water, in the form of atmospheric moisture, for example.

The outer self-healing layer has a thickness of between 0.5 μm and 200 μm, preferably between 2 μm and 150 pm and more preferably between 5 μm and 50 μm.

The innovative composite moulding of the invention, featuring a self-healing layer, for systems for solar energy generation has the following properties, in combination, as an advantage over the prior art, especially in respect of optical properties:

The transparent fraction of the composite moulding of the invention is particularly color-neutral and does not become hazy under the influence of moisture. The composite moulding, moreover, exhibits excellent weathering stability and, when equipped with the fluoropolymer-based surface described, has very good chemicals resistance, against all commercially customary cleaning products, for example. These aspects as well contribute to the retention of solar reflection over a long time period.

The material of the invention can also be used over a very long period of at least 15 years, preferably indeed at least 20 years, more preferably at least 25 years, in locations having a particularly large number of sunshine hours and particularly intense insolation, such as in the southwestern USA or in the Sahara, for example, in solar reflectors. Under these climatic conditions in particular, the self-healing layers result in a particularly long-lasting good surface quality and hence in a high efficiency—over a long period of use—of the system for solar energy generation.

The composite mouldings of the invention have self-healing properties especially when the surface is under mechanical load. This prolongs the lifetime of the solar systems even in regions with regular sandstorms or with winds with a high dust content, or when the surface is regularly cleaned using brushes.

Furthermore, the inventively employed surface enhancement can be applied in the form of a self-healing layer independently of the geometry and technical configuration of the system for solar energy generation. The systems in question may comprise, for example, flexible films, bendable panels or even sheets with a thickness of several cm.

Furthermore, the composite moulding of the invention has particular moisture stability, especially with respect to rainwater, atmospheric moisture or dew. Consequently it does not display the known susceptibility to delamination of a reflective coating from the support layers under the influence of moisture. PFEVE-based coatings possess a particularly good barrier effect with respect to water.

Furthermore, PFEVE-based coatings exhibit a particularly good barrier effect with respect to oxygen. Therefore, in a composite moulding of the invention, coatings of this kind have the further advantage that the silver layer in a solar reflector or the semiconductor layer in a photovoltaic cell are protected against oxidation.

Moreover, in addition to the self-healing properties, PFEVE-based coatings in particular already have very good scratch resistance and abrasion resistance per se, and so this effect makes an additional contribution to the longevity of the particularly preferred composite mouldings of the invention.

### DETAILED DESCRIPTION

### Process for Producing the Composite Mouldings of the Invention

Also part of the present invention, in addition to the solar system composite mouldings already described, is their production via a new process. In this process, an as yet uncoated composite moulding, having at least one layer consisting to an extent of more than 50% by weight of PMMA or a PMMA-containing polymer mixture, is coated with a PFEVE-based formulation in a thickness of between 0.5 μm and 200 μm, preferably between 2 μm and 150 μm and more preferably between 5 μm and 50 μm.

The process used is more particularly one in which the PFEVE in organic solution, together with further formulating ingredients, is applied as an “organosol” to the composite moulding, and the applied layer is subsequently dried. Coating here takes place for example by means of knife coating, roll coating, dip coating, curtain coating or spray coating. The PFEVE-based layer is crosslinked in parallel with the drying process.

The PFEVE preferably has OH groups and is crosslinked with a polyisocyanate, such as HDI, or polyisocyanates based on HDI, for example.

An example of one such suitable crosslinker is Desmodur® BL 3175 from Bayer. To accelerate the crosslinking it is possible additionally to add suitable crosslinking catalysts, such as dibutyltin dilaureate (DBTDL). In a system of this kind the amount of crosslinker is such that the ratio between OH groups and NCO groups is between 0.5 to 1.5, preferably between 0.8 and 1.2 and more preferably between 0.9 and 1.1. In the case of OH-functional polymers, they preferably have an OH number of between 20 and 120 mg KOH/g, and more preferably between 30 and 110 mg KOH/g.

These proportions between the two functional groups necessary for the crosslinking reaction, and the fraction of functional groups in the polymer used, can also be transposed to other systems, with different crosslinking mechanisms.

These figures, given by way of example, relate in particular to systems comprising HDI condensates and DBTDL. In other systems, with components which deviate more significantly in respect of the particular molecular weights or number of functionalities, the limiting ranges specified should be adapted accordingly.

This process step of coating can take place in a coating unit on a prefabricated, uncoated composite moulding. However, and with preference, coating may also be carried out in-line, directly after the production of the composite moulding. In their multi-layer film embodiment, the composite mouldings are produced by lamination. In such an event the above-described coating unit is placed in-line downstream of the laminating unit, and it is the freshly produced composite moulding that is coated.

As already described earlier on above, the PFEVE based layer can subsequently be provided optionally with one or more further functional layers.

Optional Adjuvants in the Self-Healing Layer

The self-healing layer, preferably based on a crosslinkable fluoropolymer and more preferably based on PFEVE, may comprise further adjuvants. These may, firstly, be UV stabilizers and/or UV absorbers, such as more particularly HALS compounds (highly sterically hindered amines), and also triazine-based UV absorbers. Secondly, in particular, inorganic nanoparticles as well, especially those of silicon oxides, may be mixed in for additionally improving the scratch and abrasion resistance. In this case it is possible for there to be up to 40% by weight, preferably up to 30% by weight, of these nanoparticles. It is critical here that these nanoparticles do not have light-refracting properties, and the polymer matrix is not made hazy.

Further (Inorganic) Layers

On the outer PFEVE-based layers, the composite mouldings of the invention may optionally additionally have a very thin inorganic coating for a further improvement of the surface properties. These additional coatings may be, for example, an additional scratch-resistant coating, a conductive layer, an anti-soiling coating and/or a reflection-increasing layer, or other optically functional layers. These additional layers may be applied for example by means of physical vapour deposition (PVD) or chemical vapour deposition (CVD).

An additional scratch-resistant coating may be applied optionally for further improvement of the scratch resistance. This is generally unnecessary, however, given the good quality of the composite mouldings of the invention. Scratch-resistant coatings may, for example, be silicon oxide layers, which are applied directly by means of PVD or CVD.

The optional conductive layers are metal-oxidic layers, of indium tin oxide (generally abbreviated to ITO) for example. The purpose of these layers is to prevent electrostatic charging. This has great advantages not only for the operation of the solar systems, in relation to dust attraction, for example, but also during the processing of the composite mouldings. Besides ITO it is also possible, for example, to use antimony-doped or fluorine-doped tin oxide, and also aluminium-doped zinc oxide.

In order to facilitate cleaning, the surface of the composite mouldings may additionally be furnished with a dirt-repellent or dirt-destroying coating, known as an anti-soiling coating. This coating as well may be applied by means of PVD or CVD.

Following appropriate excitation by the UV component of the solar radiation, the application of titanium dioxide brings about catalytic degradation of surface spores and algae.

The optically functional layers, in turn, are preferably reflection-increasing dielectric layers that can be used in solar reflectors. These layers are constructed, for example, of alternating silicon dioxide and titanium dioxide layers. Use may also be made, however, of magnesium fluoride, aluminium oxide, zirconium oxide, zinc sulphide or praseodymium titanium oxide. Depending on their construction, these layers may also act as a scratch-resistant coating and/or be UV-reflecting at the same time. In another possible variant of the present invention, a further, comparatively thin, extremely abrasion-resistant layer is located on the self-healing layer. This further layer is a particularly hard, thermoset layer having a thickness below preferably 5 μm, more preferably between 0.5 and 2.0 μm. This layer may be produced from a polysilazane formulation, for example.

An embodiment of this kind, with a lower thermoplastic support layer, a thinner, middle, crosslinked layer, in the form of the self-healing layer, and a very thin, outer extremely hard thermoset layer, is also called a gradient coating. Systems of this kind provide additional scratch resistance and surface stability.

### DETAILED DESCRIPTION OF THE USE

The composite mouldings of the invention can be used in particular in three different preferred embodiments.

In the first preferred embodiment, the composite moulding is a solar reflector for solar thermal collector systems.

A composite moulding of this kind, in this first preferred embodiment, has in particular, starting from the sun-facing side, at least the following layers:
a self-healing layer,
a first support layer,
an optional second support layer,
a reflective coating of silver, of a silver alloy or aluminium on the rear of the second support layer, and
optional further PVD- or CVD-applied coatings, which may be located on the top face or rear of the composite moulding or on the top face of the reflective coating.

Solar reflectors of this kind without a self-healing coating, more particularly without a PFEVE-based coating, are found in WO 2011/012342 or in WO 2011/045121, for example.

One particularly preferred variant is found in the German patent application with the application number 102011077878.0. When supplemented by the coating of the invention in the form of a PFEVE layer, this composite moulding, starting from the sun-facing side, has at least the following layers:
a PFEVE-based layer,
a first support layer which consists to an extent of more than 50% by weight of PMMA or a PMMA-containing polymer mixture and has a thickness of between 6 μm and 10 cm,
a second support layer of polycarbonate or of polyester, which has a thickness of between 0.5 μm and 2 cm,
a reflective coating of silver, of a silver alloy or aluminium on the rear of the second support layer, which has been applied by PVD or CVD, and optional further PVD- or CVD-applied coatings.

In a second, preferred embodiment, the composite moulding is a barrier film for photovoltaic systems. Such barrier films, without the self-healing layer, are described in particular in WO 2011/086272, in WO 2010/133427 or in the German patent application having the application number 102010038288.4. In accordance with the invention, a barrier film of this kind, in this embodiment, has preferably the following construction, starting from the sun-facing side:
a PFEVE-based layer,
a first carrier layer which consists to an extent of more than 50% by weight of PMMA or a PMMA-containing polymer mixture and has a thickness of between 50 and 400 μm,
a layer of adhesive, preferably an ethylene-acrylate hotmelt layer, having a thickness of between 20 and 80 μm,
a second support layer of polyester or a polyolefin, having a thickness of between 100 and 400 μm, and
an SiOₓ layer having a thickness of between 10 and 100 nm.

One or more of these layers may also be present a number of times in a laminate. Furthermore, there may also be additional layers present.

In the third preferred embodiment, the composite moulding comprises special lenses for solar thermal collector or CPV photovoltaic systems. Lenses of this kind, without a self-healing layer, are described in the German patent application having the application number 102011003311.4, for example.

The solar radiation in this embodiment can be concentrated onto the two-dimensional geometry of a photovoltaic cell, and also onto a Stirling engine or onto a two-dimensional thermal receiver of a solar thermal collector system.

In addition to these described embodiments of the composite mouldings, the present invention also encompasses the use of a composite moulding of the invention in systems for solar energy generation in general. More particularly the present invention encompasses the use of the composite mouldings of the invention for concentrating solar radiation in solar reflectors, as barrier film in flexible photovoltaic cells or as CPV lenses in solar thermal collector systems or photovoltaic systems.

For all embodiments it is possible to produce either flat sheets or else preferred curved shapes, and to install them into the systems for solar energy generation. The shaping can be carried out after the concentrators have been produced and after they have been subsequently cut to size, the shaping taking place, for example, with cold bending or hot shaping, with preference being given to a cold bending process.

### EXAMPLES

### Preliminary Stage 1

A composite film 0.15 mm thick and consisting of 0.125 mm of Plexiglas 7H PMMA, containing 2% CGX 006 and 0.6% Chimasorb 119 for UV-additization, and of 0.025 mm of Makrolon 2607 polycarbonate, is produced by means of adapter coextrusion.

This is followed by application of the reflective coating, by means of a plasma-assisted sputtering operation, to the polycarbonate side of the composite film, the reflective coating being composed, as viewed from the polycarbonate film, in the following order, 0.5 nm ZAO (zinc aluminium oxide), 100 nm Ag and 50 nm Cu.

### Comparative Example

25% by weight of 1,6-hexanediol diacrylate reactive diluent is introduced and is mixed in succession, with stirring, with 0.1% by weight of Byk UV 3510 (flow control additive), 2.5% by weight of Irgacure 184 (photoinitiator), 2.0% by weight of Tinuvin 400 (UV absorber) and 0.4% by weight of Tinuvin 123 (HALS compound). Then 70% by weight of an Ebecryl 1290 urethane acrylate is mixed in with a stirring speed of 600 rpm until the resulting mixture is clear and homogeneous.

The coating material is applied using a 12 μm wire doctor, under standard conditions, to the PMMA side of the substrate from preliminary stage 1. Curing and drying take place under a nitrogen atmosphere with an oxygen content of less than 500 ppm, by means of an Fe-doped mercury lamp, at 135 W/cm and with a belt speed of 3 m/min.

### Inventive Example

28.9% by weight of Lumiflon LF-9716 (PFEVE) is introduced in a solvent mixture of 12.4% by weight ethyl ethoxypropionate and 37.3% by weight butyl acetate and is mixed in succession, with stirring, with 0.0013% by weight of DBTDL (dibutyltin dilaurate; crosslinking catalyst), 3.4% by weight of Tinuvin 400 (UV absorber) and 1.1% by weight of Tinuvin 123 (HALS compound), until the resulting mixture is homogeneous and clear. Then 16.9% by weight of Desmodur N 3300 (polyisocyanate, crosslinker) is incorporated by stirring for 10 minutes.

The coating material is applied using a 40 μm wire doctor, under standard conditions, to the PMMA side of the substrate from preliminary stage 1. Drying and preliminary curing take place in a forced-air oven at 80° C. for 2 hours. After just 10 minutes, the coating is tack-free. Subsequent curing takes place either at room temperature over 7 days or at 80° C. for 2 hours.

Results of Testing

1. Testing of the self-healing quality:
a.) Samples are subjected to the sand trickle test of DIN 52348 (3 kg of sand).
b.) Subsequently the TSR-direct (25 mrad opening angle) is measured in accordance with ASTM G 159.
c.) This is followed by thermal conditioning at 55° C. for 2 days (typical operating temperature range of polymeric solar mirrors in a desert climate) and by a second TSR-direct measurement.

Result: The comparative example shows no recovery from the abrasion damage, whereas the sample produced in accordance with the invention exhibits 68% recovery from the damage.

2. Scratch hardness investigation with 1-3 N scoring force

Procedure: Prior to testing, the samples are surface-cleaned. Testing takes place with a ZHT 2092 Zehntner hardness testing scribe with a 0.75 mm test tip, from Bosch, an ACC 112 trolley and various compression springs. Using different defined compression springs, with different forces, the test tip is drawn in a straight line over the sample specimen.

The spring force is adjusted by pre-tensioning of the compression spring, the hardness testing scribe is placed with the tip onto the surface, and the testing instrument is pressed perpendicularly onto the surface against the spring pressure.

The trolley is then drawn over the sample in a straight line and with a speed of approximately 10 mm/s, away from the body. This operation should be repeated, with the spring force changed, until a slight injury to the test surface becomes visible. After the test cycles, the compression spring should be released.

The position of the slide on a scale shows the force (N) and hence directly the test value that corresponds to the hardness. The lowest force which has made a visible score into the material is used as the result. With the tactile measuring instrument it is possible, optionally, to determine the depth of scoring.

Result: Scoring applied using this method for imitating exposure to brush cleaning—resiles to an extent of 100% in the case of the sample according to the invention after thermal conditioning at 55° C. for 2 days. Under these conditions, the comparative sample shows no resilience at all.

1. A composite moulding, comprising:
an outer layer having self-healing properties,
wherein the composite moulding is suitable for a solar system of solar energy generation.

2. The composite moulding according to claim 1, wherein the outer layer has a glass transition temperature of from 10 to 70° C. and is crosslinked.

3. The composite moulding according to claim 1, wherein the outer layer is based on a crosslinkable fluoropolymer and comprises optional adjuvants.

4. The composite moulding according to claim 3, wherein the outer layer is based on PFEVE.

5. The composite moulding according to claim 1, wherein the outer layer has a thickness of from 0.5 to 200 μm.

6. The composite moulding according to claim 1, wherein the composite moulding is a solar reflector for a solar thermal collector system.

7. The composite moulding according to claim 6, wherein the composite moulding, from a sun-facing side, comprises:
a self-healing layer,
a first support layer,
an optional second support layer,
a reflective coating of silver, a silver alloy or aluminium on a rear side of the second support layer, and
an optional PVD- or CVD-applied coating or
a scratch-resistant coating.

8. The composite moulding according to claim 7, wherein the composite moulding, from the sun-facing side, comprises:
a PFEVE-based layer,
a first support layer which consists to an extent of more than 50% by weight of PMMA or a PMMA-comprising polymer mixture and has a thickness of from 6 μm to 10 cm,
a second support layer of polycarbonate or polyester, which has a thickness of from 0.5 μm to 2 cm,
a reflective coating of silver, a silver alloy or aluminium applied by PVD or CVD on the rear side of the second support layer, and
an optional further PVD- or CVD-applied coating or
a thermoset polysilazane layer.

9. The composite moulding according to claim 1, wherein the composite moulding is a barrier film for a photovoltaic system.

10. The composite moulding according to claim 9, wherein the composite moulding, from the sun-facing side, comprises:
a PFEVE-based layer,
a first carrier layer which consists to an extent of more than 50% by weight of PMMA or a PMMA-comprising polymer mixture and has a thickness of from 50 to 400 μm,
a layer of adhesive having a thickness of from 20 to 80 μm,
a second support layer of polyester or a polyolefin having a thickness of from 100 to 400 μm, and
a SiOx layer having a thickness of from 10 to 100 nm.

11. The composite moulding according to claim 1, wherein the composite moulding comprises a lens for a solar thermal collector system or a CPV photovoltaic system.

12. The composite moulding according to claim 4, wherein the PFEVE-based layer is coated with at least one of a scratch-resistant coating, a conductive layer, an anti-soiling coating, a reflection-increasing layer or another optically functional layer.

13. A process comprising:
a coating a composite moulding with a PFEVE-based formulation, thereby obtaining a PFEVE-based layer in a thickness of from 0.5 to 200 μm,
wherein
the composite moulding comprises a layer which consists to an extent of more than 50% by weight of PMMA or a PMMA-comprising polymer mixture, and
the composite moulding is suitable for a solar system.

14. The process according to claim 13, wherein the PFEVE-based formulation is applied as an organic solution to the composite moulding and is subsequently dried.

15. The process according to claim 14, wherein said coating takes place in-line directly after producing the composite moulding.

16. The process according to claim 15, wherein the PFEVE-based layer is subsequently provided with a further functional layer.

17. The composite moulding according to claim 1, wherein the composite moulding is suitable for concentrating solar radiation in a solar reflector, as a barrier film in a flexible photovoltaic cell or as a CPV lens in a solar thermal collector system or a photovoltaic system.

18. A solar system of solar energy generation, comprising the composite moulding according to claim 1.
